(19) United States
(12) Patent Application Publication
(10) Pub. No.: US 2006/0220058 A1
(43) Pub. Date: Oct. 5, 2006

(54) Multiple tunnel junction thermotunnel device on the basis of ballistic electrons

(76) Inventor: Avto Tavkhelidze, Tbilisi (GE)

Correspondence Address: Borealis Technical Limited, 23545 N W Skyline Blvd, North Plains, OR, 97133-9205, US

(21) Appl. No.: 10/560,139

(22) PCT Filed: Jun. 9, 2004
(86) PCT No.: PCT/US04/18688

§ 371 Date: Dec. 9, 2005

(30) Foreign Application Priority Data
Jun. 10, 2003 (GB) 0313317.0

(51) Int. Cl. H01L 29/00

(52) U.S. Cl. 257/104

(57) ABSTRACT

The present invention is a tunnel diode, in which the space between the emitter electrode and the collector electrode is occupied by a porous material which has a thickness less then the free mean free path of an electron in the porous material. The present invention also includes heat pumping and power generation devices comprising the tunnel diode.

### TECHNICAL FIELD

The present invention relates to tunnel junction diodes. It also relates to devices for heat pumping and electrical energy generation, particularly to thermotunnel devices. The present invention utilizes ballistic electrons and quantum mechanical effects that work only for ballistic electrons.

### BACKGROUND ART

In order to operate thermoelectric heat pumps and energy converters in a high efficiency regime one needs to select electrons by energy. In the case where mostly only high-energy electrons are used for heat transport, efficiency is considerably increased.

In U.S. Pat. No. 3,169,200, an energy converter comprising multiple tunnel junctions connected in series is described. Tunnel junctions comprise two metal electrodes separated by a thin insulator layer. When a thermal gradient is maintained across the device, thermally excited electrons tunnel trough the tunnel junctions and generate output voltage. One disadvantage of such a converter is that it does not have a high enough selectivity for electrons by energy because it does not utilize ballistic electrons. Another disadvantage results from the losses due to thermal conduction. Tunnel barriers are very thin (of the order of 10 Angstroms) and thermal backflow in a particular tunnel junction is very high because of the use of a solid insulator layer between metallic electrodes. Because of this, 10⁵ junctions need to be connected in series to reduce thermal backflow and obtain efficient heat to electrical energy transfer. Fabrication of such a number of tunnel junctions connected in series appears to be practically impossible.

There remains a need in the art therefore for a device having fewer elements, which is easier to fabricate, and in which losses due to thermal conduction are further reduced.

Previously we have described a thermotunnel device that could be used both for heat pumping and electrical energy generation (U.S. Pat. No. 6,417,060; WO99/13562). Such a thermotunnel device comprises two metal electrodes separated by thin vacuum gap, as is shown in FIG. 1. Electrons tunnel from a hot emitter 100 to a cold collector 102 through a vacuum gap 104. FIG. 1 also shows the energy diagram for the device. Here E_{f} is Fermi energy of emitter and Eᵥ vacuum energy level. Consider two electrons sitting on different quantum energy levels in the emitter: one electron 106 has a higher energy, and the other electron 108 has a lower energy. Let the probabilities of tunnelling be ρ₁ and ρ₂ respectively, as shown. The probability of tunnelling is greater for the electron having the higher energy ρ₁>ρ₂. Thus the single tunnel barrier selects electrons by energy. However this selection process is not enough by itself because the density of energy states decreases exponentially when the energy is increased (depending on the work function of the metal and its temperature). Overall, the tunnelling current from the interval dE is the probability of tunnelling multiplied by the density of energy states. Consequently the contribution of low energy electrons to the tunnelling current is still considerable.

FIG. 2 shows an emitter electrode 100, a collector electrode 102 and a number of islands 210, 212 disposed between them. The islands are preferably metallic. Each of the islands has a thickness b. For the sake of simplicity, two such islands are shown, but any number n may be utilized. The thickness, b, of the islands is chosen such that their total thickness is less than the mean free path of an electron in the particular material, L. Under these conditions, for the case when electrons are ballistic, (n−1)b<L, and the electron can travel through many tunnel junctions without entering into thermal equilibrium with the electron gas and lattice in the metallic islands.

Thus the thickness of the islands and number of the islands is low enough that an electron can travel through such a system without interaction with lattice inside the islands. For such a system, the probabilities of tunneling for two ballistic electrons 106 and 108 sitting on different quantum energy levels are ρ₁ⁿ and ρ₂ⁿ correspondently. The ratio of probabilities of tunneling will be ρ₁ⁿ/ρ₂ⁿ=(ρ₁/ρ₂)ⁿ. Thus the ratio of probabilities of tunneling for multiple junctions is n-th degree of the ratio of probabilities of the single junction shown in FIG. 1. Given formula is true only in the case the same electron tunnels through all of the tunnel barriers (ballistic tunneling). It is obvious that this ratio increases very sharply as the number of tunnel junctions connected in series is increased. This means that selectivity is greatly increased in multiple tunnel junctions connected in series, and a thermotunnel device based on such multiple tunnel junctions will have a high efficiency.

Such multiple tunnel junctions are very difficult to fabricate. Whilst it is possible to achieve a thin vacuum gap over large areas for a single tunnel junction, duplicating it and connecting junctions in series is not possible for current nano-engineering techniques. This is because very thin islands are needed to obtain ballistic transport regime: the integrated width of all the islands should be less than mean free path of the electron in the given material (mean free path of the electron is in the range of 1-100 nm for metals). Thin films of such thickness are almost impossible to fabricate; in addition it remains unclear how a vacuum gap between them could be maintained and stabilized under the influence of the electrostatic forces between islands.

One practical solution is porous,materials and particularly porous silicon that has pore size of the order of nanometers. Such material has been used for photoluminescence device fabrication (Nakajima et al. (2002) Appl. Phys. Lett. 81:2472-2474). The device is composed of a semitransparent top electrode, a thin film of fluorescent material, a nano-crystalline porous silicon layer, an n-type silicon wafer, and an ohmic back contact. When a positive dc voltage is applied to the top electrode with respect to the substrate, electrons injected into the nano-crystalline porous silicon layer are accelerated via multiple tunneling through interconnected silicon nano-crystallites, and reach the outer surface as energetic hot or quasi-ballistic electrons. Experimental results obtained from porous silicon show clear filtering of electrons by energies.

Another work (Ozaki et al. (1995) Jap. J. Appl. Phys. 24:946-949) investigates the nature of electron filtering mechanism in porous material and experimental results showed that tunneling is responsible for filtering electrons by energy.

### DISCLOSES OF INVENTION

From the foregoing, it may be appreciated that a need has arisen for a process and a device in which the benefits of multiple tunnel junctions can be harnessed for increasing selectivity of tunnelling.

Here we disclose a solution that uses porous materials as multiple vacuum tunnel barriers to increase selectivity of tunnelling. We suggest the use of such a material as an electron filter in a thermoelectric device.

The present invention is a tunnel diode, in which the space between the emitter electrode and the collector electrode is occupied by a porous material which has a thickness less then the free mean free path of an electron in the porous material. The present invention also includes heat pumping and power generation devices comprising the tunnel diode.

### BRIEF DESCRIPTION OF DRAWINGS

For a more complete explanation of the present invention and the technical advantages thereof, reference is now made to the following description and the accompanying drawings, in which:

FIG. 1 is a diagrammatic representation of a thermotunnel device of the prior art.

FIG. 2 is a diagrammatic representation of a multiple tunnel junction device on the basis of ballistic electrons.

FIG. 3 is a diagrammatic representation of a multiple tunnel junction thermoelectric device of the present invention.

FIG. 4 is a diagrammatic representation of an apparatus for the conversion of energy of the present invention.

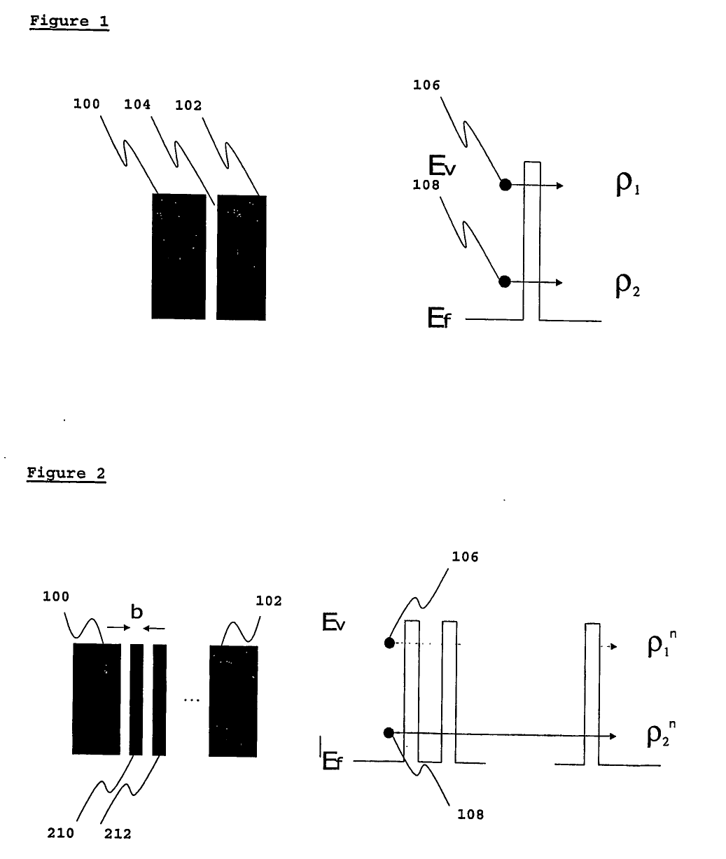

### BEST MODE FOR CARRYING OUT THE INVENTION

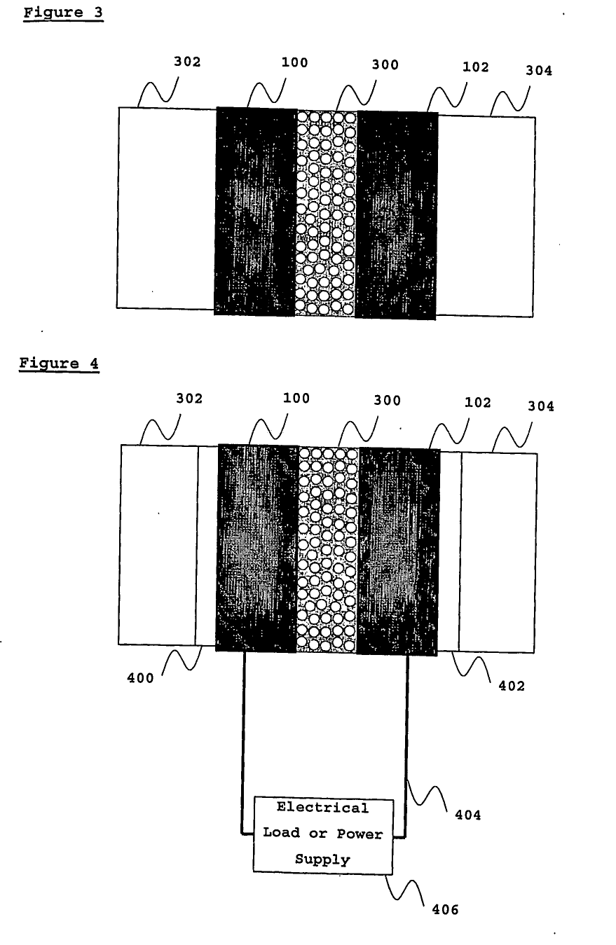

Embodiments of the present invention and their technical advantages may be better understood by referring to FIG. 3.

FIG. 3 shows an emitter electrode 100, a collector electrode 102 and a porous layer 300 disposed between them. The thickness of the porous material is selected so that it is less than mean free path of the electron in given material and for given pore density. Typically, the thickness of the porous material is 1-100 nm. In a preferred embodiment, the porous layer is porous silicon. In a further preferred embodiment, the porous silicon is doped to alter the mean free path of the electron. Electrode 100 is thermally connected to a heat source 302 and electrode 102 is thermally connected to heat sink 304. Electrons in electrode 100 are excited to high energies by the heat source, and high-energy electrons tunnel to electrode 102, producing a voltage drop between the two electrodes. As the electrons move from one electrode to the other, they tunnel through the many pores inside the porous material. Because of this multiple tunneling, electrons are sharply selected according to their energy, which means that only electrons having the highest energies can take part in heat transport. Thus the efficiency of energy conversion is increased by the filtering effect of porous material relative to a device utilizing a single tunnel junction.

Referring now to FIG. 4, which shows in diagrammatic form an apparatus for the conversion of energy, a source of thermal energy 302 is connected via a thermal interface 400 to an emitter electrode 100. A heat sink 304 is connected via a thermal interface 402 to a collector electrode 102. A porous material 300 is disposed between the emitter electrode and the collector electrode as shown. An electrical circuit 404 connects the two electrodes.

For power generation, an electrical load 406 forms part of circuit 404. The source of thermal energy may be solar, or may be from the combustion of fuel, or may be waste heat. The source of thermal energy promotes the flow of electrons from emitter to collector through the electrical load via the external circuit.

For the conversion of electrical energy to heat pumping capacity, an electrical power supply 406 forms part of circuit 404. The electrical power supply applies a voltage bias to the electrodes, and causes electrons to flow from the emitter electrode to the collector electrode, resulting in a transfer of thermal energy from the emitter to the collector. The source of thermal energy may be cooler than the heat sink.

It might be considered that the heat conductance of the porous layer could deleteriously influence the efficiency of such a device because of heat backflow. However heat conductivity of porous silicon has been investigated and it is found that porous material has a very low heat conductivity (Zeng et al. (1995) Transactions of ASME Journal of Heat Transfer 117:758-761). Porous silicon is therefore used for heat insulation in some experimental devices. It is believed that the main mechanism responsible for the low heat conductivity is due to a change in the physics of heat transfer, resulting from the pore dimensions being less than mean free path of atmospheric gas molecules.

### INDUSTRIAL APPLICABILITY

The present invention may be applied to a variety of tunnel junction applications, including heat pumping and power generation.

1. A tunnel diode comprising:
(a) an emitter electrode, in contact with
(b) a porous material, in contact with
(c) a collector electrode
wherein said porous material has a thickness which is less then the free mean free path of an electron in said porous material.

2. The tunnel diode of claim 1 in which said porous material comprises porous silicon.

3. The tunnel diode of claim 1 in which said porous material comprises doped porous silicon.

4. The tunnel diode of claim 1 in which said thickness is in the range of 1 to 100 nm.

5. The tunnel diode of claim 1 additionally comprising a heat source in contact with said emitter electrode.

6. The tunnel diode of claim 1 additionally comprising a heat sink in contact with said collector electrode.

7. Apparatus for the conversion of energy comprising:
(a) a source of energy;
(b) an emitter electrode connected to said source of energy;
(c) a collector electrode;
(d) a porous material disposed between said emitter electrode and said collector electrode;
(e) an electrical circuit connecting said electrodes; and
wherein said porous material has a thickness which is less then the free mean free path of an electron in said porous material.

8. The apparatus of claim 7 in which said porous material comprises porous silicon.

9. The apparatus of claim 7 in which said porous material comprises doped porous silicon.

10. The apparatus of claim 7 in which said thickness is in the range of 1 to 100 nm.

11. The apparatus of claim 7, wherein the conversion of energy is the conversion of thermal energy to electrical energy, wherein said source of energy comprises a source of thermal energy, and wherein said apparatus further comprises:
a) a first thermal interface thermally connecting said source of energy to said emitter electrode;
b) a second thermal interface thermally connecting a heat sink means to said collector electrode;
c) an electrical load, electrically connected by said circuit between said collector electrode and said emitter electrode.

12. The apparatus of claim 11 wherein said source of thermal energy is of solar origin.

13. The apparatus of claim 7, wherein the conversion of energy is the conversion of electrical energy to heat pumping capacity, and wherein said apparatus further comprises:
a) a heat source and a heat sink, wherein said heat source is thermally connected to said emitter electrode and said heat sink is thermally connected to said collector electrode, and,
b) an electrical power supply, electrically connected by said circuit between said collector electrode and said emitter electrode for applying a voltage bias to said electrodes, said electrical power supply providing said energy source.

14. The apparatus of claim 13 wherein said heat source may be cooler than said heat sink.
